(19) United States
(12) Patent Application Publication
(10) Pub. No.: US 2020/0358339 A1
(43) Pub. Date: Nov. 12, 2020

(54) External electromagnetic pulse attack shielding system for motor controller of electric vehicle

(71) Applicant: Lei HAN, Beijing (CN)

(72) Inventors: Lei HAN, Beijing (CN); Wanhui HAN, Beijing (CN)

(21) Appl. No.: 16/095,372

(22) PCT Filed: Mar. 28, 2017
(86) PCT No.: PCT/CN2017/078343

§ 371 Date: Dec. 7, 2018

(30) Foreign Application Priority Data
Apr. 5, 2016 (CN) 2016103105983

(51) Int. Cl. H02K 11/02; H05K 9/00; H02K 9/19

(52) U.S. Cl. CPC H02K 11/02; H02K 9/19; H05K 9/0049

(57) ABSTRACT

A shielding system for an electric vehicle motor controller to shield external electromagnetic pulse attack. Signal lines, control line protectors, first power surge protectors, second power surge protectors and third power surge protectors installed inside the outer shield body of the motor controller absorb the current induced by the external electromagnetic field on the shield, signal line, first power line and second power line, coolant inlet and coolant outlet, preventing the remaining current from inducing a new strong electromagnetic field to attack the motor controller. The cooling liquid cooling system may keep the temperature of the motor controller of the electric vehicle not change when running under heavy load. The above technology may ensure the motor controller of the electric vehicle running according to the design requirements.

### TECHNICAL FIELD

This application relates to an electric vehicle motor controller, in particular to an external electromagnetic pulse attack shielding system for electric vehicle motor controller to preventing it from being interfered by external strong electromagnetic field.

### BACKGROUND

According to definition of the motor controller of GB/T 18488.1-2001 Electric vehicle motor and its controller technical conditions, the motor controller is the device that controls the energy transmission between the main traction power supply and the motor, and the motor controller comprises an external control signal interface circuit, a motor control circuit and a drive circuit. As the main components of electric vehicles, motors, drives and motor controllers play an important role in the whole vehicle system of electric vehicles. The research in related fields has important theoretical and practical signifimayce. The motor controller acts as the control center for the entire brake system. The motor controller consists of an inverter and a controller. The inverter receives the DC power delivered from the battery, and inverts the DC power into a three-phase AC to supply power for the automobile motor. The controller receives signals such as motor speed and feeds back to the meter. When braking or acceleration behavior occurs, the controller controls the frequency of the inverter to rise and fall, thereby achieving the purpose of acceleration or deceleration.

According to GB/T 18655-2010 limits and measurement methods for the protection of vehicle receiver based on vehicle, ship and internal combustion engine radio disturbance characteristics, the electromagnetic field emission intensity of electric vehicles is limited. AC motor drive system for electric vehicle consists of inverter's power circuit, control circuit, chassis, radiator, cable and other parts. And the main components of the inverter's power circuit are power modules or components, such as PIM or IGBT. These power modules, such as IGBTs, operate in a high-speed on-off mode during operation, forming a high-frequency dv/dt between their collector and emitter, resulting in broadband electromagnetic interference over a frequency range of tens of megahertz. As the motor becomes lighter and more efficient, the switching speed of the power module is also higher and higher, which makes the electromagnetic interference generated by the power module stronger. The electromagnetic interferences affects the normal operation of the vehicle electronic components through transmitting and radiating (maybe through cables and frames), probably causing the motor end bearing current to be too large and damaging the bearing or burning out the motor insulation; thus the electromagnetic interference generated by the motor drive system is not only related to its own operational reliability, but also affects the electromagnetic compatibility, safe operation capability and operational reliability of the entire vehicle and adjacent vehicles. Therefore, studying the mechanism and suppression method of electromagnetic interference has practical signifimayce for the development of electric vehicles. There are two kinds of electromagnetic interference of the electric vehicle motor drive system: conductive electromagnetic interference and radiated electromagnetic interference. The interference generated by the high-speed on-off of the power device in the inverter power loop firstly conducts interference in the system components, connectors and cables. Because the length of the power cable for electric vehicles is long, the conducted interference radiates externally through the DC power cable and the motor three-phase AC power cable, so conducted interference is the main source of interference. The current standard for components on electric vehicle “GB/T 18655-2010 Vehicle, ship and internal combustion engine radio disturbance characteristics for the protection of on-board receiver limits and measurement methods” only specifies the test method for low-voltage system conducted electromagnetic interference, the conduction voltage of the low-voltage power line and the conduction current of the signal line.
1. Inadequacies of existing electromagnetic field shielding systems and motor controllers
2. In an electric vehicle, the motor controller is a key component for realizing the conversion of the DC power supply of the battery and the AC power of the motor. The motor controller is expected to operate continuously and reliably. There are many types of motor controllers, but the layout is similar. And there are some problems in reliability and durability verification, such as poor heat dissipation of the driver module, affecting the lifetime of IGBT (Insulated Gate Bipolar Transistor) and insulated gate bipolar transistor. The control board and the drive board are not well isolated, and the electromagnetic compatibility is poor, affecting the overall efficiency of the system. The particularly serious part is that the existing electric motor motor controller has only a thick metal shell on the outside. After being interfered by the external electromagnetic field, the electromagnetic field is magnetically saturated on the metal shell instantaneously. After the electromagnetic field breaks the metal shell, the core electronic components in the integrated circuit of the electric vehicle motor controller are attacked instantly, making the motor controller not work normally and losing control of the electric vehicle drive motor, which may lead to a traffic accident.
3. Chinese Patent 201420282762.0 discloses an electromagnetic field shielding system for an electric vehicle motor controller, using power surge protector to protect one line (a two-phase power line or three-phase power line of the motor controller in the shield body) without simultaneously protecting the other line, then the strong current induced by the external electromagnetic field may attack the chip of the motor controller along the unprotected power line, making the patent fail.
4. Three aspects of electromagnetic pulse protection

2.1. Shielding: shielding makes use of shielding body to block or reduce the transmission of electromagnetic energy to achieve electromagnetic protection, allowing no electromagnetic field to reach the protected devices.

2.2. Grounding: grounding is the connection between the electronic devices and the earth through appropriate methods and approaches in order to improve the stability of electronic equipment and effectively restrain the influence of external electromagnetic field, avoiding the interference and damage caused by discharging caused by charge accumulation.

2.3. Filter: a filter may be formed into selective network with resistance, inductance and capacitance to achieve the filtering effect. A filter may also be made of lossy material such ferrite to filter. (Reference: Sun yongjun, Principles and Protection of Electromagnetic Pulse [J], Space Electronic Technology, 2004(3))

3. The world's most advanced power surge protector (SPD): signal lines and circuit control protection are the world's leading power purification, precision instrument protection and power surge protection products. The sine wave that may track the filtering and special chemical packaging patent technology includes surge protection and filtering technology, which are in line with the technology requirements of electromagnetic pulse protection. The product (SPD) has the following advantages:

3.1 Because of the multi-level protection mechanism, the residual pressure may reach 0V. The surge voltage after diversion is generally between 2.5 KV and 15 KV. Devices that equipped with SPD may achieve very low residual pressure, and zero volt may be reached in some special industry. The smaller the residual pressure is, the better the protection effect is.

3.2 The response speed of SPD is less than 1 ns, which may prevent the second lightning, induced lightening and the internal flow of electrical transient voltage suppressor (TVS) effectively. The response time of TVS two tube is less than 1 ns. The advantages goes are bidirectional protection, fast speed, large power of absorbing surge (transient power up to several kw), clamp voltage is easy to control, low current leakage, no damage limit, small volume.

3.3 The shell adopts NEMA 4 standard, and the shell is waterproof, fireproof, explosion-proof and anti-static.

3.4 The patented sine wave ORN tracking technology may eliminate surge and harmonic wave accurately. The sine wave ORN with enhanced patent may shift positively and negatively according to a certain sine wave, eliminating the surge's dirty electricity and cleaning the electricity environment, remaining low residual pressure value. In the computer communication system and electronic devices, the electromagnetic pulse is coupled to the circuit through conducting wires, and the over voltage energy of the product is transmitted to the devices through the circuit to interfere or damage the equipment. When the wires are coupled, the energy is over voltage. ORN filtering technology may ensure the power and signal clean and prevent computer systems or electronic devices from interference or damage of electromagnetic pulse through the tracking technology.

3.5 The one and only chemical packaging patent technology may ensure the devices' reliable performance in a long time. The special chemical seal may rapidly absorb the heat produced during the process of surge protection to protect and prolong the service life of components to protect the security of the system.

3.6 The true 10 mode (full mode) protection may filter waves between lines, blocking all possible channels of surge include blocking the channel between the lines and the ground to create a perfect protection.

3.7 The capacitor design is hybrid multi-module with both thermal insurance and electric insurance.

3.8 The surge protection product is the only one that is earth-free, using patented sine wave tracking technology, special chemical packaging, and nanosecond TVS components, using ten mode protection and diversified module to make sure that the product may not release energy through the ground. For the grounding system is not perfect for the military mobile communication system, this product may do the surge filter protection without grounding. (Reference: Amerimay Company Product Specification Series)

4. The principle of electromagnetic shielding and the selection of shielding material manufacturing materials

4.1. Low-frequency electromagnetic waves have higher magnetic field components than high-frequency electromagnetic waves. For very low interference frequencies, the permeability of shielding materials is much more important than that at high frequencies. The basic principle of shielding low frequency electromagnetic interference is the parallel bypass of the magnetic circuit. Using a magnetically conductive material provides magnetic bypass to reduce the magnetic flux density inside the shield, while increasing the eddy current loss, part of the energy is converted into heat energy consumption. The thicker the shielding material, the smaller the magnetic resistance and the greater the eddy current loss, and the better the shielding effect. Materials with high conductivity and low magnetic permeability have almost no shielding effect on the magnetic field component of electromagnetic waves.

4.2 Permeability is also related to the strength of the applied magnetic field. When the applied magnetic field strength is low, the magnetic permeability increases with the increase of the applied magnetic field. When the applied magnetic field strength exceeds a certain value, the magnetic permeability drops sharply. At this time, the material is saturated, and once the material is saturated, the magnetic shielding leak out. The higher the magnetic permeability of the material, the easier the material is to saturate. Therefore, in a very strong magnetic field, a material with a high magnetic permeability does not have good shielding effectiveness. The magnetic permeability of low carbon steel is about 4000, and the saturation strength is about 22000. The low carbon steel plate has good mechanical properties, good weldability, easy processing and low saturation. So the low carbon steel plate is the first choice for low frequency electromagnetic shielding materials.

5. Inadequacies in existing technology

5.1. Closed shield body with simple structure is convenient and low cost. The common ultra-low frequency electromagnetic shielding device is composed of single-layer high-magnetic alloy, single-layer structure ultra-low frequency electromagnetic shielding device (only suitable for shielding). Lower requirements (electromagnetic shielding coefficient is 20-30 dB) for places with high shielding requirements (electromagnetic shielding coefficient is 75-90 dB) are not suitable, even if the shielding body is thickened, the shielding may not achieve the desired effect.

5.2. Among the main measures of anti-electromagnetic pulse (shielding, grounding, filtering), shielding is often used. But complete electromagnetic pulse protection is not provided for the cable on the equipment or system is the most effective electromagnetic pulse receiving and transmitting antenna. Especially for systems with external antennas and systems with multiple devices connected by cables, simple shielding may not meet the corresponding protection requirements.

5.3. The existing single-layer or multi-layer electromagnetic shielding device has no power surge protector (SPD), signal line and control line protector installed on the outer shield surface, between the inner and outer layers of the multilayer shield, and the inner shield. There is no power surge protector (SPD) installed in the ground wire. The strong electric field and strong magnetic field generated by electromagnetic pulses induce voltages of several kilovolts to tens of thousands of volts and currents of several thousand amps to tens of thousands of amps on power line cables, signal line cables, and grounding conductors. The cable, signal cable, and ground wire enter the shield and destroy or protect the protected computer inside the inner shield.

### Content

The magnetic saturation caused by the outer layer of the existing electric motor controller may lead to the electromagnetic field penetrating the outer casing and destroying the integrated circuit composed of the internal electronic components of the electric motor controller, then the electric vehicle loses control. This embodiment provides a shielding system for an electric vehicle motor controller to shield external electromagnetic pulse attack, and the system comprises a first spiral conduit, a third spiral conduit, a fifth spiral conduit, and an eighth spiral conduit mounted outside the shield, the tenth spiral conduit blocks the external electromagnetic field from directly entering the inside of the shield, the signal line installed inside the shield, the control line protector, the first power surge protector, the second power surge protector and the third power source form a shield that shields external electromagnetic field.

The signal line, the control line protector, the first power surge protector, the second power surge protector, and the third power surge protector installed inside the shield absorb the external electromagnetic field on the upper surface of the shield and the signal line. The upper surface of the first power line and the upper side of the second power line, the current induced on the coolant inlet and the coolant outlet protect the motor controller installed inside the shield. The cooling liquid cooling system may make the electric motor controller's temperature of the electric vehicle unchanged.

The beneficial effects of this embodiment are as follows: a shielding system for an electric vehicle motor controller to shield external electromagnetic pulse attack may protect the internal electronic components of the electric vehicle motor controller from being damaged by external strong electromagnetic fields, and the cooling liquid cooling system can make the electric vehicle run under a large load. The temperature of the motor controller of the electric vehicle does not change. The above technology may protect the motor controller of the electric vehicle from operating according to the design requirements.

### BRIEF DESCRIPTION OF DRAWINGS

FIG. 1 is a narrow structural view of this embodiment;

FIG. 2 is a plan view of the shield of this embodiment;

FIG. 3 is a diagram showing the connection of the signal line inlet and outlet and the internal circuit of this embodiment;

FIG. 4 and FIG. 5 are connection diagrams of the power cord inlet and outlet conduits and internal wiring of this embodiment;

FIG. 6 and FIG. 7 are connection diagrams of a coolant inlet and a outlet conduit of this embodiment;

FIG. 8 and FIG. 9 are structural views of a shield mesh of this embodiment;

FIG. 10 is a perspective view of the motor controller of this embodiment;

FIG. 11 is a connection diagram of a power surge protector and a power line of this embodiment;

FIG. 12 is a schematic exploded view of the core components of the motor controller of this embodiment.

### SPECIFIC IMPLEMENTATION PLAN

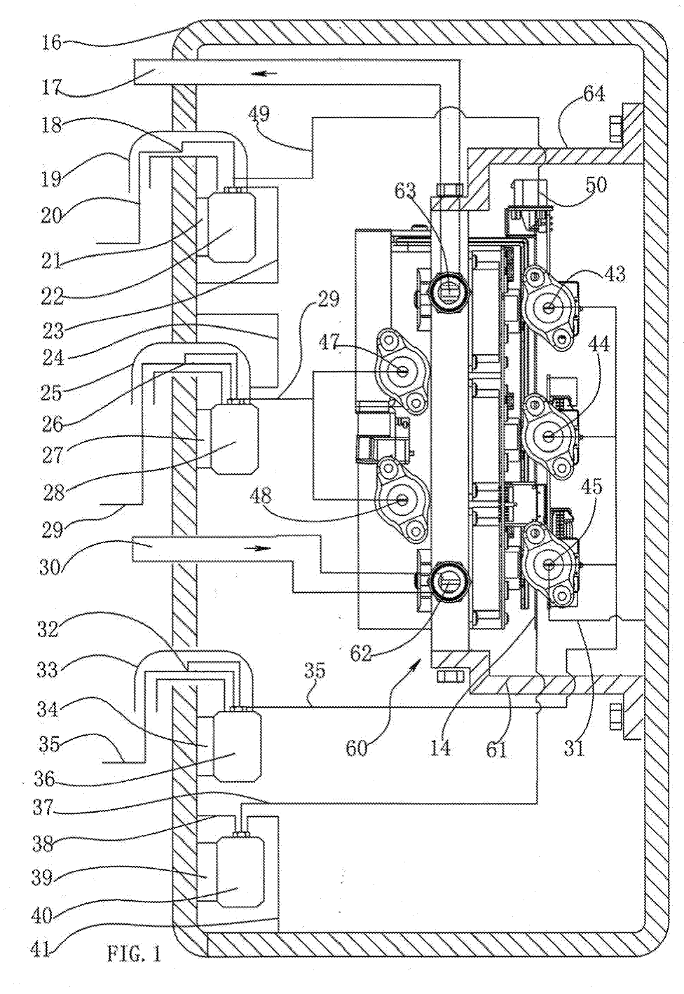

FIG. 1 shows the first bracket 21 is fixed on the inner surface of the shield body 16, and the signal line and control circuit protector 22 are fixed on the first bracket 21; the second bracket 27 is fixed on the inner surface of the shield body 16, and the first power surge protector 28 is fixed on the second bracket 27; the third bracket 34 is fixed on the inner surface of the shield body 16, and the second power surge protector 36 is fixed on the third bracket 34; the fourth bracket 39 is fixed on the inner surface of the shield body 16, and the third power surge protector 40 is fixed on the fourth bracket 39; the motor controller 60 is mounted and fixed to the inside of the shield 16 through the fifth bracket 61 and the sixth bracket 64. The first shield duct 19, the second shield duct 25, and the third shield duct 33 (all bent at right angle from both ends of the conductive magnetically permeable metal) are mounted on the shield 16 by the way of soldering.

FIGS. 1-2 shows the shield body 16 comprising a lower housing 71 and an upper cover 72 is a rectangular box with no right angle; the upper cover 72 is fixed to the lower housing 71 by the screw 75; the corners of the shield 16 are all in the shape of a circular arc, and the shield 16 is fixed to the electric vehicle by the bracket 74.

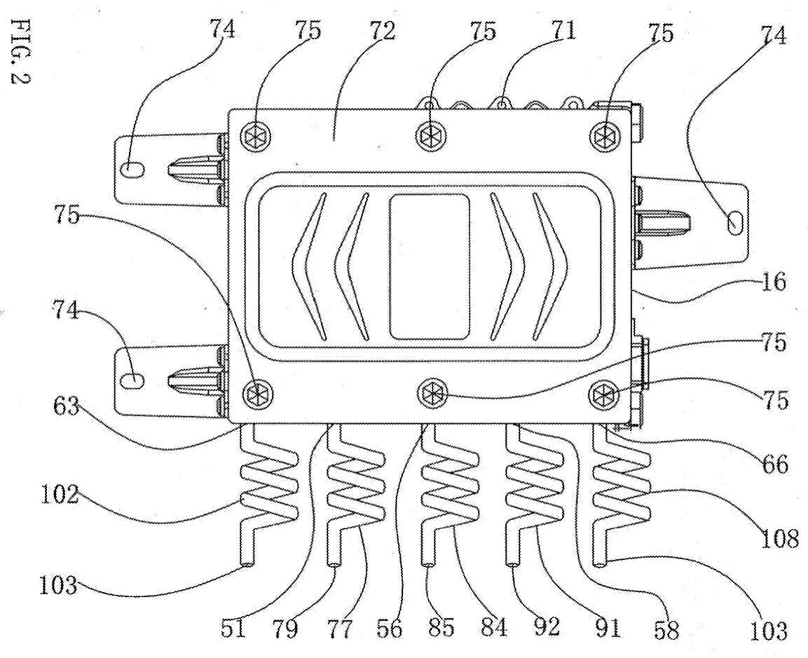

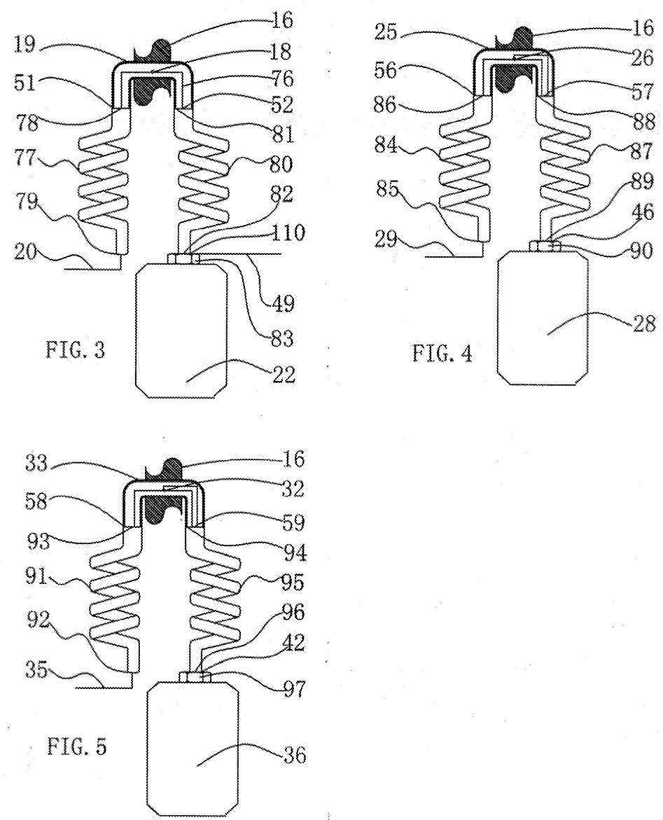

FIG. 1 and FIG. 3 show the first spiral conduit 77 and the second spiral conduit 80 are respectively mounted at both ends of the first shielded conduit 19 bent at right angle at both ends, and the tenth interface 78 of the first spiral conduit 77 is connected to the seventh interface 51 of the first shielding duct 19; the eleventh interface 81 of the second spiral duct 80 is connected to the eighth interface 52 of the first shielding duct 19. The first wire 49 passes through the first signal line outlet 110 of the second spiral conduit 80, and the tenth interface 82 of the second spiral conduit 80 is closely connected to the first interface 83 of the upper portion of the signal line and control line protector 22. On the outside of the shield 16, the signal line 20 enters into the first helix catheter 77 from the ninth connector 79 of the first helix catheter 77, and then is connected to the second conductor 76 of the signal line and control line protector 22 at the connection point 18. The first connection point 18 is at an intermediate position between the seventh interface 51 and the eighth interface 52; the first wire 49 of the signal line and control line protector 22 is connected to the signal line interface 50 of the motor controller 60, and the signal line 20 is connected in series with the signal line and control line protector 22; the first grounding wire 23 of the signal line and control line protector 22 is the protective ground line PE of the signal line and control line protector 22, and the first grounding wire 23 is connected to the inner surface of the shield 16 to dissipate the absorbed energy in the shield 16.

FIG. 4, FIG. 11, and FIG. 1 show the first power line 29 is connected in parallel with the first power surge protector 28. The fifteenth interface 86 of the third spiral conduit 84 is connected to the third interface 56 of the second shield conduit 25; the sixteenth interface 88 of the fourth spiral conduit 87 is connected to the fourth interface 57 of the second shield conduit 25. The seventeenth port 89 of the fourth spiral conduit 87 is tightly connected to the upper second port 90 of the first power surge protector 28. On the outside of the shield 16, the first power line 29 enters the third spiral conduit 84 from the fourteenth interface 85 of the third helical conduit 84, and enters the second shielded conduit 25 through the fifteenth interface 86 and the third interface 56 of the second shielded conduit 25; after entering the second shielded conduit 25, the first power line 29 enters the interior of the shield 16 and is connected in parallel with the first power surge protector 28 at the second connection point 26, and the second connection point 26 is in the middle of the third interface 56 and the fourth interface 57. The first power line 29 is composed of two wires, and is divided into two lines inside the shield body 16 after passing through the second shielding conduit 25, the fourth interface 57, the fourth spiral conduit 87 and the first power line outlet 46 (the first line of the two lines is a positive line connected to the positive power source interface 47 of the motor controller 60; the second line is a negative line and is connected to the negative power supply interface 48 of the motor controller 60. The second grounding conductor 24 of the first power surge protector 28 is the protective grounding wire PE of the first power surge protector 28 and is connected to the inner surface of the shield 16 to dissipate the absorbed energy in the shield 16.

FIG. 5, FIG. 11, and FIG. 1 show the second power line 35 is connected in parallel with the second power surge protector 36, and the second power line 35 comprises a phase line L, a neutral line N, and a protective ground line G. The twentieth interface 93 of the fifth spiral conduit 91 is connected to the fifth interface 58 of the third shield conduit 33; the twenty-first interface 94 of the sixth spiral conduit 95 is connected to the sixth interface 59 of the third shield conduit 33. The twenty-second interface 96 of the sixth spiral conduit 95 is tightly connected to the upper twenty-third interface 97 of the second power surge protector 36. The second power wire 35 enters the fifth spiral conduit 91 from the eighteenth interface 92 of the fifth spiral conduit 91, and then enters the third shield conduit 33 from the fourth interface 58; after the second power wire 35 enters the third shielding conduit 33, the second power wire 35 is connected in parallel with the second power surge protector 36 to the third connection point 32 before going into the shield 16. The third connection point 32 is at an intermediate position between the fifth interface 58 and the sixth interface 59, and the second power supply line 35 passes through the third shielding conduit 33 and the sixth spiral conduit 95, and goes through the second power supply line's outlet 42 of the third shielding conduit 33. Then the second power supply line 35 is separated into three lines: the phase line L is connected to the first power port 43 of the motor controller 60, and the neutral line N is connected to the second power port 44 of the motor controller 60; the protective ground wire G is connected to the third power interface 45 of the motor controller 60. The third ground wire 31 of the motor controller 60 is the protective ground wire PE of the motor controller 60 and is connected to the inner surface of the shield 16 to dissipate the absorbed energy in the shield 16.

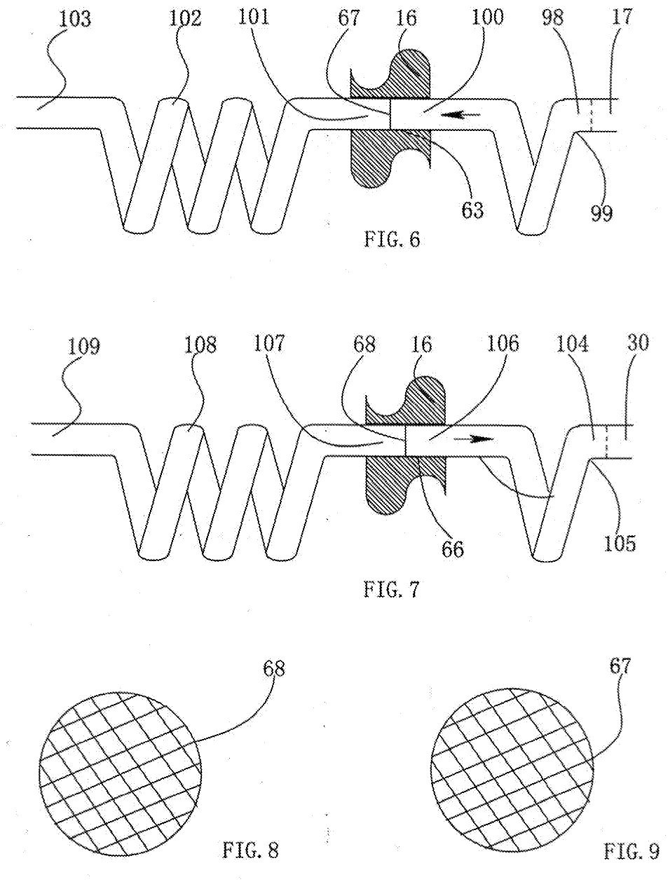

FIGS. 6-9 and FIG. 1, the coolant outlet pipe 17 is first connected to the twenty-fourth port 98 of the seventh spiral conduit 99, and the fifth interface 100 of the twentieth of the seventh spiral conduit 99 is connected to the nineteenth interface 101 of the eighth spiral conduit 102 outside the shield 16 through the coolant outlet 63 of the shield 16. The first shield mesh 67 is mounted between the twenty-fifth interface 100 and the nineteenth interface 101 of the shield 16. The twenty-fifth interface 100, the nineteenth interface 101 and the first shielding net 67 are welded together,

The coolant inlet pipe 30 is first connected to the twenty-seventh interface 104 of the ninth spiral conduit 105, and the twenty-eighth interface 106 of the ninth spiral conduit 105 is connected to the twenty-ninth interface 107 of the tenth spiral conduit 108 through the coolant inlet 66 of the shield 16. And the twenty-eighth interface 106, the twenty-ninth interface 107 and the second shield mesh 68 are welded together. After the first shielding net 67 and the second shielding net 68 and the shielding body 16 form a leak proof shielding body, the third power surge protector 40 may absorb the current induced by the external electromagnetic field in the cooling liquid.

FIG. 11 and FIG. 1 show that the third power surge protector 40 can absorb the large current induced on the shielding plate 14 of the motor controller 60 after the first wire 37 of the third power surge protector 40 is connected to the shield slab 14 of the motor controller 60. After the second wire 38 of the third power surge protector 40 is connected to the shield 16, the third power surge protector 40 can absorb the large current induced on the shield 16 by the external electromagnetic field. The fourth grounding conductor 41 of the third power surge protector 40 is a protective grounding wire PE, and is connected to the inner surface of the shielding body 16 to lead the energy the third power supply surge protector 40 absorbed to the shielding body 16.

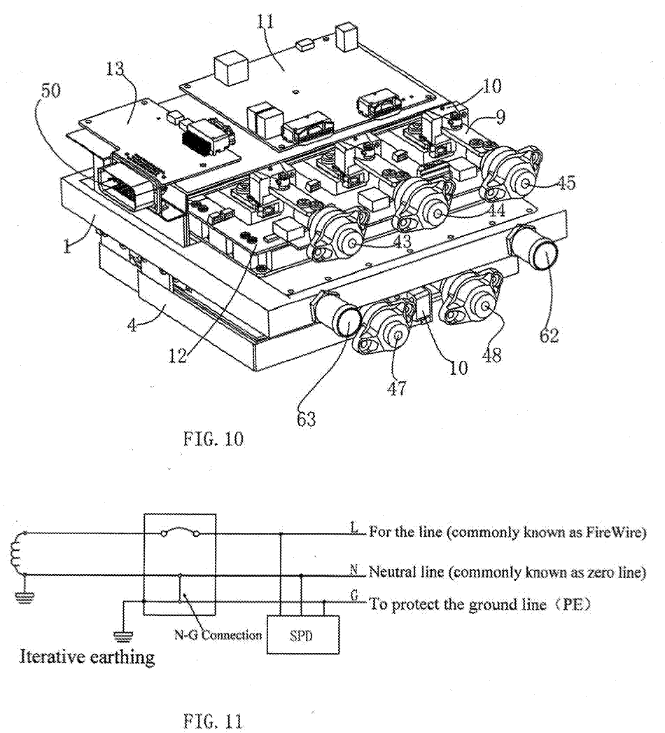

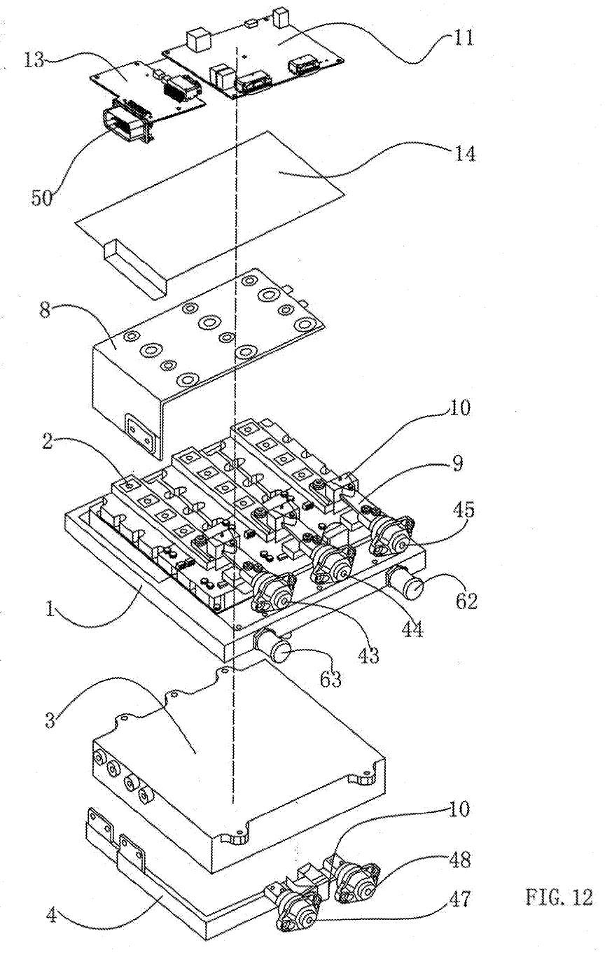

FIG. 10, FIG. 12 and FIG. 1 show that the motor controller comprises a radiator 1, a plurality of power modules 2, a capacitor module 3 and a DC composite copper bar 4. A cooling liquid passage is opened on the radiator 1, and a cooling a coolant inlet 62 and a coolant outlet 63 (on the radiator 1) are connected to the liquid passage. A plurality of power modules 2 and capacitor module 3 are respectively mounted on the upper surface and the lower surface of the radiator 1, both radiating heat through the radiator 1. A positive power input interface 47 and a negative power input interface 48 are installed on the one end of the DC composite copper bar 4, and the power module 2 and the capacitor module 3 are connected to the other end electrically. The output end of the power module 2 outputs an AC power source through the first output power interface 43, the second output power interface 44 and the third output power interface. And the input end of the power module 2 and the DC composite copper bar 4 are electrically connected through the input pole piece 8, inputting direct current from the DC composite copper bar 4 to each power module 2. One end of the output copper bar 9 is connected to the output end of the power module 2, and the current sensor 10 is mounted on some or all of the output copper bar 9 and the DC composite copper bar 4. And all the output copper bar 9 are provided with current sensor 10. A control circuit board 11 and a driving circuit board 12 are mounted on the upper surface of the power module 2, and a shielding board 14 is disposed between the control circuit board 11 and the upper surface of the power module 2. The control circuit board 11 is driven by the driving circuit board 12. An adapter circuit board 13 is also mounted on the upper surface of the power module 2, and the adapter circuit board 13 is electrically connected to the control circuit board 11, converting and inputting the received signal to the control circuit board 11.

The working principle of the shielding system of the electric vehicle motor controller: a powerful electromagnetic field generated externally induces a current on the signal line 20, and the signal line and the control line protector 22 absorb the current induced by the signal line 20, preventing the large current from entering the shield 16 through the first shielded conduit 19 along the signal line 20.

The first power surge protector 28 absorbs the current induced by the external strong electromagnetic field on the first power line 29 to prevent the current from penetrating the shield 16 to form a new strong electromagnetic field.

The second power surge protector 36 absorbs the current induced by the external strong electromagnetic field on the second power line 35 to prevent the current from penetrating the shield 16 to form a new strong electromagnetic field.

The third power surge protector 40 absorbs the current induced by the external strong electromagnetic field on the shield 16 and the motor controller 60 through the third power surge protector first connection line 37 and the second connection line 38. After the current is absorbed, the current cannot reach saturation on the shield 16 and the electromagnetic field cannot penetrate the shield 16.

What is claimed is:

1. A shielding system of electric vehicle motor controller to shield external electromagnetic pulse attack comprises a first helical conduit, a third helical conduit, a fifth helical conduit, an eighth helical conduit and a tenth helical conduit mounted outside the shield body to block external electromagnetic field from entering directly into the shield, and the signal line and control line protector, the first power surge protector, the second power surge protector and the third power surge protector installed inside the shield together with the shield body form a whole shield body to shield external electromagnetic field;

2. A shielding system of electric vehicle motor controller to shield external electromagnetic pulse attack according claim 1, the system comprising: a first bracket 21 is fixed on the inner surface of the shield body 16, and the signal line and control circuit protector 22 are fixed on the first bracket 21; the second bracket 27 is fixed on the inner surface of the shield body 16, and the first power surge protector 28 is fixed on the second bracket 27; the third bracket 34 is fixed on the inner surface of the shield body 16, and the second power surge protector 36 is fixed on the third bracket 34; the fourth bracket 39 is fixed on the inner surface of the shield body 16, and the third power surge protector 40 is fixed on the fourth bracket 39; the motor controller 60 is mounted and fixed to the inside of the shield 16 through the fifth bracket 61 and the sixth bracket 64; the first shield conduit 19, the second shield conduit 25, and the third shield conduit 33 (all bent at right angle from both ends of the conductive magnetically permeable metal) are mounted on the shield 16 by the way of soldering; a shield body 16 comprising a lower housing 71 and an upper cover 72 is a rectangular box with no right angle; the upper cover 72 is fixed to the lower housing 71 by the screw 75; the corners of the shield 16 are all in the shape of a circular arc, and the shield 16 is fixed to the electric vehicle by the bracket 74; a first spiral conduit 77 and a second spiral conduit 80 are respectively mounted at both ends of the first shielded conduit 19 bent at right angle at both ends, and the tenth interface 78 of the first spiral conduit 77 is connected to the seventh interface 51 of the first shielding duct 19; the eleventh interface 81 of the second spiral duct 80 is connected to the eighth interface 52 of the first shielding duct 19; the first wire 49 passes through the first signal line outlet 110 of the second spiral conduit 80, and the tenth interface 82 of the second spiral conduit 80 is closely connected to the first interface 83 of the upper portion of the signal line and control line protector 22. On the outside of the shield 16, the signal line 20 enters into the first helix catheter 77 from the ninth connector 79 of the first helix catheter 77, and then is connected to the second conductor 76 of the signal line and control line protector 22 at the connection point 18; the first connection point 18 is at an intermediate position between the seventh interface 51 and the eighth interface 52; the first wire 49 of the signal line and control line protector 22 is connected to the signal line interface 50 of the motor controller 60, and the signal line 20 is connected in series with the signal line and control line protector 22; the first grounding wire 23 of the signal line and control line protector 22 is the protective ground line PE of the signal line and control line protector 22, and the first grounding wire 23 is connected to the inner surface of the shield 16 to dissipate the absorbed energy in the shield 16. a first power line 29 is connected in parallel with the first power surge protector 28; the fifteenth interface 86 of the third spiral conduit 84 is connected to the third interface 56 of the second shield conduit 25; the sixteenth interface 88 of the fourth spiral conduit 87 is connected to the fourth interface 57 of the second shield conduit 25; the seventeenth port 89 of the fourth spiral conduit 87 is tightly connected to the upper second port 90 of the first power surge protector 28; on the outside of the shield 16, the first power line 29 enters the third spiral conduit 84 from the fourteenth interface 85 of the third helical conduit 84, and enters the second shielded conduit 25 through the fifteenth interface 86 and the third interface 56 of the second shielded conduit 25; after entering the second shielded conduit 25, the first power line 29 enters the interior of the shield 16 and is connected in parallel with the first power surge protector 28 at the second connection point 26, and the second connection point 26 is in the middle of the third interface 56 and the fourth interface 57. The first power line 29 is composed of two wires, and is divided into two lines inside the shield body 16 after passing through the second shielding conduit 25, the fourth interface 57, the fourth spiral conduit 87 and the first power line outlet 46 (the first line of the two lines is a positive line connected to the positive power source interface 47 of the motor controller 60; the second line is a negative line and is connected to the negative power supply interface 48 of the motor controller 60; the second grounding conductor 24 of the first power surge protector 28 is the protective grounding wire PE of the first power surge protector 28 and is connected to the inner surface of the shield 16 to dissipate the absorbed energy in the shield 16; a second power line 35 is connected in parallel with the second power surge protector 36, and the second power line 35 comprises a phase line L, a neutral line N, and a protective ground line G; the twentieth interface 93 of the fifth spiral conduit 91 is connected to the fifth interface 58 of the third shield conduit 33; the twenty-first interface 94 of the sixth spiral conduit 95 is connected to the sixth interface 59 of the third shield conduit 33; the twenty-second interface 96 of the sixth spiral conduit 95 is tightly connected to the upper twenty-third interface 97 of the second power surge protector 36; the second power wire 35 enters the fifth spiral conduit 91 from the eighteenth interface 92 of the fifth spiral conduit 91, and then enters the third shield conduit 33 from the fourth interface 58; after the second power wire 35 enters the third shielding conduit 33, the second power wire 35 is connected in parallel with the second power surge protector 36 to the third connection point 32 before going into the shield 16; the third connection point 32 is at an intermediate position between the fifth interface 58 and the sixth interface 59, and the second power supply line 35 passes through the third shielding conduit 33 and the sixth spiral conduit 95, and goes through the second power supply line's outlet 42 of the third shielding conduit 33; then the second power supply line 35 is separated into three lines: the phase line L is connected to the first power port 43 of the motor controller 60, and the neutral line N is connected to the second power port 44 of the motor controller 60; the protective ground wire G is connected to the third power interface 45 of the motor controller 60; the third ground wire 31 of the motor controller 60 is the protective ground wire PE of the motor controller 60 and is connected to the inner surface of the shield 16 to dissipate the absorbed energy in the shield 16; a coolant outlet pipe 17 is first connected to the twenty-fourth port 98 of the seventh spiral conduit 99, and the fifth interface 100 of the twentieth of the seventh spiral conduit 99 is connected to the nineteenth interface 101 of the eighth spiral conduit 102 outside the shield 16 through the coolant outlet 63 of the shield 16; the first shield mesh 67 is mounted between the twenty-fifth interface 100 and the nineteenth interface 101 of the shield 16; the twenty-fifth interface 100, the nineteenth interface 101 and the first shielding net 67 are welded together; the coolant inlet pipe 30 is first connected to the twenty-seventh interface 104 of the ninth spiral conduit 105, and the twenty-eighth interface 106 of the ninth spiral conduit 105 is connected to the twenty-ninth interface 107 of the tenth spiral conduit 108 through the coolant inlet 66 of the shield 16; the twenty-eighth interface 106, the twenty-ninth interface 107 and the second shield mesh 68 are welded together; after the first shielding net 67 and the second shielding net 68 and the shielding body 16 form a leak proof shielding body, the third power surge protector 40 may absorb the current induced by the external electromagnetic field in the cooling liquid;

3. A shielding system of electric vehicle motor controller to shield external electromagnetic pulse attack according claim 1, the system comprising: a first bracket 21 is fixed on the inner surface of the shield body 16, and the signal line and control circuit protector 22 are fixed on the first bracket 21; the second bracket 27 is fixed on the inner surface of the shield body 16, and the first power surge protector 28 is fixed on the second bracket 27; the third bracket 34 is fixed on the inner surface of the shield body 16, and the second power surge protector 36 is fixed on the third bracket 34; the fourth bracket 39 is fixed on the inner surface of the shield body 16, and the third power surge protector 40 is fixed on the fourth bracket 39; the motor controller 60 is mounted and fixed to the inside of the shield 16 through the fifth bracket 61 and the sixth bracket 64; the first shield duct 19, the second shield duct 25, and the third shield duct 33 (all bent at right angle from both ends of the conductive magnetically permeable metal) are mounted on the shield 16 by the way of soldering. a shield body 16 comprising a lower housing 71 and an upper cover 72 is a rectangular box with no right angle; the upper cover 72 is fixed to the lower housing 71 by the screw 75; the corners of the shield 16 are all in the shape of a circular arc, and the shield 16 is fixed to the electric vehicle by the bracket 74. a first spiral conduit 77 and a second spiral conduit 80 are respectively mounted at both ends of the first shielded conduit 19 bent at right angle at both ends, and the tenth interface 78 of the first spiral conduit 77 is connected to the seventh interface 51 of the first shielding duct 19; the eleventh interface 81 of the second spiral duct 80 is connected to the eighth interface 52 of the first shielding duct 19; the first wire 49 passes through the first signal line outlet 110 of the second spiral conduit 80, and the tenth interface 82 of the second spiral conduit 80 is closely connected to the first interface 83 of the upper portion of the signal line and control line protector 22; on the outside of the shield 16, the signal line 20 enters into the first helix catheter 77 from the ninth connector 79 of the first helix catheter 77, and then is connected to the second conductor 76 of the signal line and control line protector 22 at the connection point 18; the first connection point 18 is at an intermediate position between the seventh interface 51 and the eighth interface 52; the first wire 49 of the signal line and control line protector 22 is connected to the signal line interface 50 of the motor controller 60, and the signal line 20 is connected in series with the signal line and control line protector 22; the first grounding wire 23 of the signal line and control line protector 22 is the protective ground line PE of the signal line and control line protector 22, and the first grounding wire 23 is connected to the inner surface of the shield 16 to dissipate the absorbed energy in the shield 16. a first power line 29 is connected in parallel with the first power surge protector 28; the fifteenth interface 86 of the third spiral conduit 84 is connected to the third interface 56 of the second shield conduit 25; the sixteenth interface 88 of the fourth spiral conduit 87 is connected to the fourth interface 57 of the second shield conduit 25; the seventeenth port 89 of the fourth spiral conduit 87 is tightly connected to the upper second port 90 of the first power surge protector 28; on the outside of the shield 16, the first power line 29 enters the third spiral conduit 84 from the fourteenth interface 85 of the third helical conduit 84, and enters the second shielded conduit 25 through the fifteenth interface 86 and the third interface 56 of the second shielded conduit 25; after entering the second shielded conduit 25, the first power line 29 enters the interior of the shield 16 and is connected in parallel with the first power surge protector 28 at the second connection point 26, and the second connection point 26 is in the middle of the third interface 56 and the fourth interface 57; the first power line 29 is composed of two wires, and is divided into two lines inside the shield body 16 after passing through the second shielding conduit 25, the fourth interface 57, the fourth spiral conduit 87 and the first power line outlet 46 (the first line of the two lines is a positive line connected to the positive power source interface 47 of the motor controller 60; the second line is a negative line and is connected to the negative power supply interface 48 of the motor controller 60; the second grounding conductor 24 of the first power surge protector 28 is the protective grounding wire PE of the first power surge protector 28 and is connected to the inner surface of the shield 16 to dissipate the absorbed energy in the shield 16; a second power line 35 is connected in parallel with the second power surge protector 36, and the second power line 35 comprises a phase line L, a neutral line N, and a protective ground line G; the twentieth interface 93 of the fifth spiral conduit 91 is connected to the fifth interface 58 of the third shield conduit 33; the twenty-first interface 94 of the sixth spiral conduit 95 is connected to the sixth interface 59 of the third shield conduit 33; the twenty-second interface 96 of the sixth spiral conduit 95 is tightly connected to the upper twenty-third interface 97 of the second power surge protector 36; the second power wire 35 enters the fifth spiral conduit 91 from the eighteenth interface 92 of the fifth spiral conduit 91, and then enters the third shield conduit 33 from the fourth interface 58; after the second power wire 35 enters the third shielding conduit 33, the second power wire 35 is connected in parallel with the second power surge protector 36 to the third connection point 32 before going into the shield 16; the third connection point 32 is at an intermediate position between the fifth interface 58 and the sixth interface 59, and the second power supply line 35 passes through the third shielding conduit 33 and the sixth spiral conduit 95, and goes through the second power supply line's outlet 42 of the third shielding conduit 33; then the second power supply line 35 is separated into three lines: the phase line L is connected to the first power port 43 of the motor controller 60, and the neutral line N is connected to the second power port 44 of the motor controller 60; the protective ground wire G is connected to the third power interface 45 of the motor controller 60; the third ground wire 31 of the motor controller 60 is the protective ground wire PE of the motor controller 60 and is connected to the inner surface of the shield 16 to dissipate the absorbed energy in the shield 16; a coolant outlet pipe 17 is first connected to the twenty-fourth port 98 of the seventh spiral conduit 99, and the fifth interface 100 of the twentieth of the seventh spiral conduit 99 is connected to the nineteenth interface 101 of the eighth spiral conduit 102 outside the shield 16 through the coolant outlet 63 of the shield 16. The first shield mesh 67 is mounted between the twenty-fifth interface 100 and the nineteenth interface 101 of the shield 16. The twenty-fifth interface 100, the nineteenth interface 101 and the first shielding net 67 are welded together; the coolant inlet pipe 30 is first connected to the twenty-seventh interface 104 of the ninth spiral conduit 105, and the twenty-eighth interface 106 of the ninth spiral conduit 105 is connected to the twenty-ninth interface 107 of the tenth spiral conduit 108 through the coolant inlet 66 of the shield 16; the twenty-eighth interface 106, the twenty-ninth interface 107 and the second shield mesh 68 are welded together; after the first shielding net 67 and the second shielding net 68 and the shielding body 16 form a leak proof shielding body, the third power surge protector 40 may absorb the current induced by the external electromagnetic field in the cooling liquid; a third power surge protector 40 can absorb the large current induced on the shielding plate 14 of the motor controller 60 after the first wire 37 of the third power surge protector 40 is connected to the shield slab 14 of the motor controller 60; after the second wire 38 of the third power surge protector 40 is connected to the shield 16, the third power surge protector 40 can absorb the large current induced on the shield 16 by the external electromagnetic field; the fourth grounding conductor 41 of the third power surge protector 40 is a protective grounding wire PE, and is connected to the inner surface of the shielding body 16 to lead the energy the third power supply surge protector 40 absorbed to the shielding body 16; a motor controller comprises a radiator 1, a plurality of power modules 2, a capacitor module 3 and a DC composite copper bar 4; a cooling liquid passage is opened on the radiator 1, and a cooling a coolant inlet 62 and a coolant outlet 63 (on the radiator 1) are connected to the liquid passage; a plurality of power modules 2 and capacitor module 3 are respectively mounted on the upper surface and the lower surface of the radiator 1, both radiating heat through the radiator 1; a positive power input interface 47 and a negative power input interface 48 are installed on the one end of the DC composite copper bar 4, and the power module 2 and the capacitor module 3 are connected to the other end electrically; the output end of the power module 2 outputs an AC power source through the first output power interface 43, the second output power interface 44 and the third output power interface; the input end of the power module 2 and the DC composite copper bar 4 are electrically connected through the input pole piece 8, inputting direct current from the DC composite copper bar 4 to each power module 2; one end of the output copper bar 9 is connected to the output end of the power module 2, and the current sensor 10 is mounted on some or all of the output copper bar 9 and the DC composite copper bar 4; all the output copper bar 9 are provided with current sensor 10; a control circuit board 11 and a driving circuit board 12 are mounted on the upper surface of the power module 2, and a shielding board 14 is disposed between the control circuit board 11 and the upper surface of the power module 2; the control circuit board 11 is driven by the driving circuit board 12; an adapter circuit board 13 is also mounted on the upper surface of the power module 2, and the adapter circuit board 13 is electrically connected to the control circuit board 11, converting and inputting the received signal to the control circuit board 11.
